(19) United States
(12) Patent Application Publication
(10) Pub. No.: US 2021/0098324 A1
(43) Pub. Date: Apr. 1, 2021

(54) OPTOELECTRONIC CHIP SCALE PACKAGE WITH PATTERNED DAM STRUCTURE

(71) Applicant: POWERTECH TECHNOLOGY INC., HSINCHU COUNTY (TW)

(72) Inventors: Hung-Hsin Hsu, HSINCHU COUNTY (TW); Wen-Hsiung Chang, HSINCHU COUNTY (TW)

(21) Appl. No.: 16/583,286

(22) Filed: Sep. 26, 2019

(51) Int. Cl. H01L 23/31; H01L 27/146; H01L 21/768

(52) U.S. Cl. CPC H01L 23/3114; H01L 21/76898; H01L 27/14618

(57) ABSTRACT

By using a photosensitive material coating or laminating on the substrate, an opening well structure with plurality of openings and pillars is formed by photolithography or mechanical processing to have patterns corresponding to the active sensor areas of the chip die so as to provide improved support on the substrate for the cover glass. The overall package structure is then reinforced without the risk of cracking the substrate.

### BACKGROUND OF THE INVENTION

### 1. Field of the Invention

The invention relates to a chip package, and more particularly, to an optoelectronic chip scale package with patterned dam structure.

### 2. Description of the Prior Art

For optoelectronic chip scale packages such as light sensors, proximity sensors, or the category of CMOS image sensor (CIS), a dam should be layered on the surface of the substrate before the cover glass is further layered atop. The dam on the surface of the substrate and the die is protective for the die from dust falling on the sensor active area of the die and is provided as an adhesive and support layer between the substrate and the cover glass. The coating/lamination process of the dam should be carried out not covering the sensor active area (or a group of sensor active areas of the die), which means the dam should be provided as a hollow structure with cut-out central part. Mechanically, the support for the cover glass above the substrate lies all on the dam around the sensor active areas and given the trend of larger die accompanied by higher resolution and improved image quality, the dam's support for the cover glass has been reached its limit and is more likely to cause crack on these packages that have enlarged die and sensor active areas.

### SUMMARY OF THE INVENTION

It is therefore an objective to provide a chip scale package with improved dam structure for larger die and sensor active areas.

According to an embodiment of the invention, a chip scale package with patterned dam structure is provided and includes a substrate, a chip die, a dam, and a cover glass. The substrate is a support structure for the chip scale package. The chip die is disposed on a top side of the substrate. The chip die has a plurality of sensor active areas. The dam is layered on the top side of the substrate and covering the chip die. The dam has an opening well structure on the plurality of sensor active areas. The opening well structure includes a plurality of pillars distributed on the chip die where a plurality of openings is formed among the plurality of pillars. The plurality of openings respectively corresponds in position to the plurality of sensor active areas and the plurality of pillars is supported by the chip die. The cover glass is layered on the dam and is supported by the dam.

According to another aspect of the invention, the dam is made of photosensitive material and the opening well structure is formed by photolithography.

According to another aspect of the invention, the opening well structure of the dam is formed by laser engraving, dry etching, wet etching, mechanical drilling, or micromachining.

According to another aspect of the invention, the dam is coated or laminated on the substrate.

According to another aspect of the invention, the plurality of openings of the opening well structure is independent from one another and circle-shaped.

According to another aspect of the invention, the plurality of openings of the opening well structure is interconnected with one another and circle-shaped.

According to another aspect of the invention, the plurality of openings of the opening well structure is interconnected with one another and hexagonal.

According to another aspect of the invention, the plurality of openings of the opening well structure is independent from one another and oblong.

According to another aspect of the invention, the opening well structure with the plurality of openings is supportive to the substrate when a series of backside procedures is carried out on a bottom side of the substrate opposite to the top side.

According to another aspect of the invention, the chip die is an optoelectronic chip, a light sensor, a proximity sensor, a micro lens, or a CMOS image sensor.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is an illustration showing cross section of an embodiment of a chip scale package with patterned dam structure according to the invention.

FIG. 2 is an illustration showing a first embodiment of a patterned dam according to the invention.

FIG. 3 is an illustration showing a second embodiment of a patterned dam according to the invention.

FIG. 4 is an illustration showing a third embodiment of a patterned dam according to the invention.

FIG. 5 is an illustration showing a fourth embodiment of a patterned dam according to the invention.

### DETAILED DESCRIPTION

Certain terms are used throughout the following description and claims to refer to particular system components. As one skilled in the art will appreciate, manufacturers may refer to a component by different names. In the following discussion and in the claims, the terms “include” and “comprise” are used in an open-ended fashion. Also, the term “couple” is intended to mean either an indirect or direct electrical/mechanical connection. Thus, if a first device is coupled to a second device, that connection may be through a direct electrical/mechanical connection, or through an indirect electrical/mechanical connection via other devices and connections.

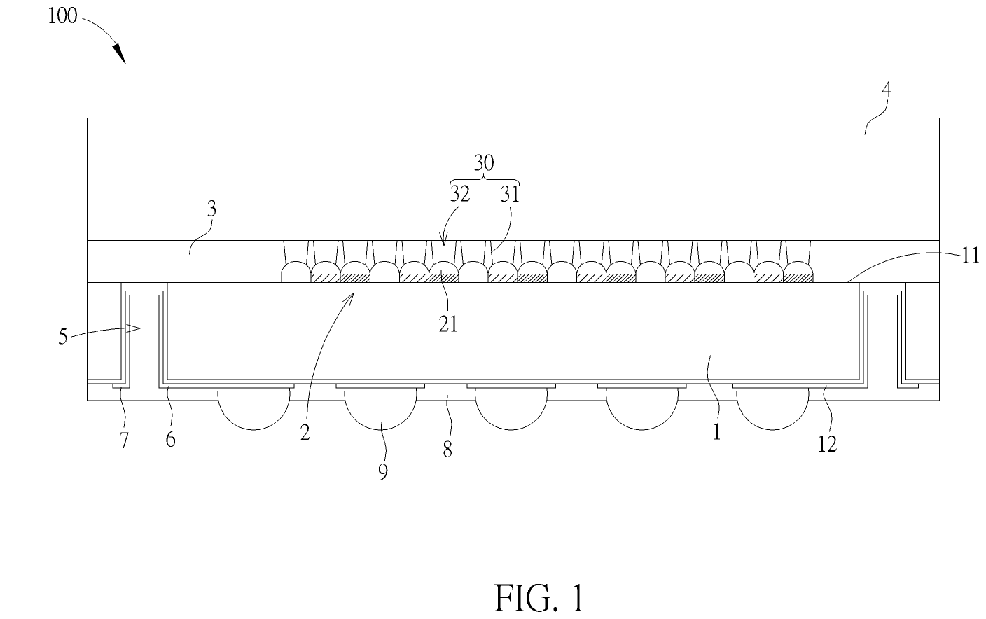

Please refer to FIG. 1. FIG. 1 is an illustration showing cross section of an embodiment of a chip scale package with patterned dam structure according to the invention. A chip scale package 100 according to the invention is provided as, preferably but not limited to, a CIS (CMOS image sensor) CSP (chip scale package) package with TSV (through silicon via) structure, where an optoelectronic chip die or chip die with sensor active areas is contained. The chip scale package 100 includes a substrate 1 having a top side 11 and a bottom side 12 opposite to each other, a chip die 2, a dam 3, and a cover glass 4.

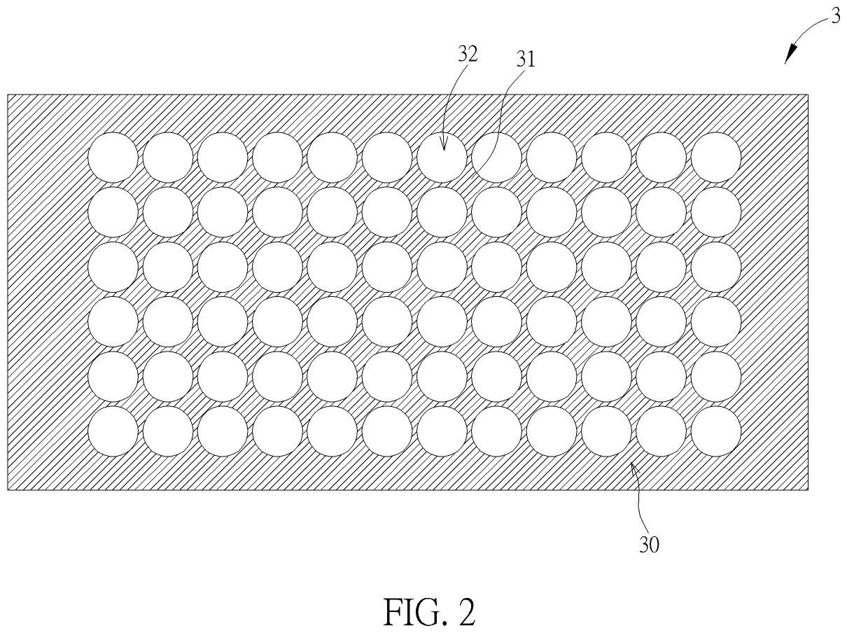

Please also refer to FIG. 2, which is an illustration showing a first embodiment of a patterned dam according to the invention. The substrate 1 is a support structure for the chip scale package 100 with the top side 11 the chip die 2 is disposed on. In the embodiment of the invention, the chip die 2 is an optoelectronic chip, a light sensor, a proximity sensor, a micro lens, or a CMOS image sensor that has a plurality of sensor active areas 21 which requires to be exposed through the cover glass 4. The dam 3 is layered on the top side 11 of the substrate 1 for supporting the cover glass 4 and also for protective purpose of the chip die 2 from dust and humidity. In the packaging procedure, the dam 3 may be coated or laminated on the substrate 1, covering the chip die 3, for follow-up adhesion between the substrate 1 and the cover glass 4.

In the embodiment, the dam 3 to be coated or laminated on the substrate 1 is made of photosensitive material that can be formed by photolithography to have specific pattern to correspond to the pattern of the active sensor areas the chip die 3 has. More specifically, the dam 3 is exposed and developed in photolithography procedure to form an opening well structure 30 on the plurality of sensor active areas 21. Once formed, the opening well structure 30 has a plurality of pillars 31 distributed on the chip die 2 where a plurality of openings 32 is formed among the plurality of pillars 31. The plurality of openings 32 then has a pattern that respectively corresponds in position to the plurality of sensor active areas 21 with the plurality of pillars 31 supported by the chip die 2. In other embodiment, the opening well structure 30 of the dam 3 may also be formed by laser engraving, dry etching, wet etching, mechanical drilling, or micromachining to form the pattern as composed by the pillars 31 and openings 32.

After the dam 3 with patterned opening well structure 30 is formed and coated/laminated on the substrate 1, the cover glass 4 is layered and adhered thereon and supported by the dam 3. The support for the cover glass 4 on the top side 11 of the substrate 1 not only comes from the peripheral of the dam 3 but also from the plurality of pillars 31 of the opening well structure 30.

It should be noted that the opening well structure 30 in the invention also contributes to the support for the substrate 1 when the chip scale package 100 undergoes a following series of backside procedures on the bottom side 12 of the substrate 1. The backside procedures may include, but not limited to, backside grinding for reducing the thickness of the substrate 1, shield coating of dielectric layer 6 such as SiOx or SiNx, etching for TSV 5, Layout of RDL 7 (using Cupper, Aluminum or any conductive materials . . . ), coating of passivation 8 (Solder mask, polymeric resin, inorganic dielectric . . . ), and soldering balls 9, etc.

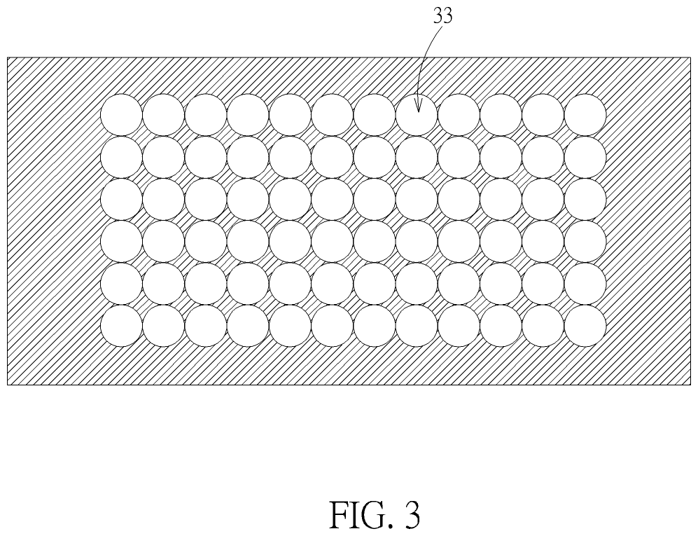

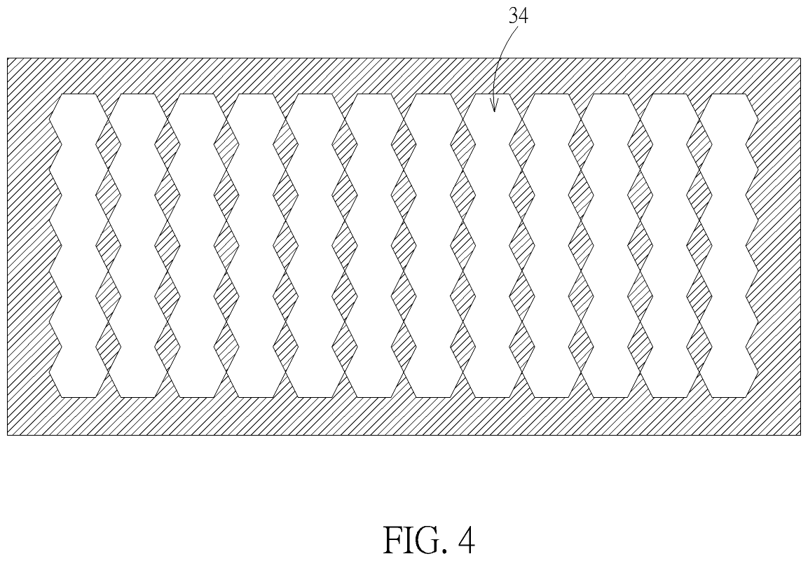

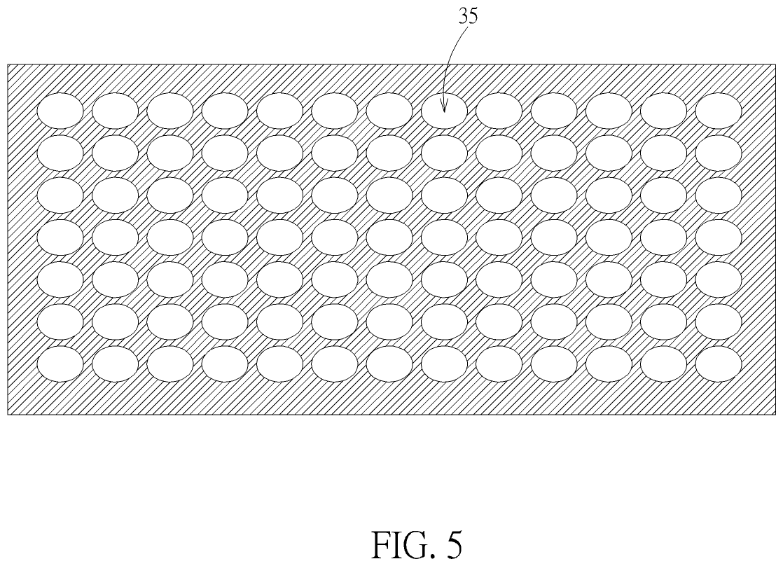

In the embodiment of FIG. 2, the plurality of openings 32 of the opening well structure 30 is independent from one another and circle-shaped. FIG. 3 to FIG. 5 shows other embodiments of the patterned dam according to the invention. For example, FIG. 3 shows a second embodiment of a patterned dam where the openings 33 are interconnected with one another and circle-shaped. FIG. 4 shows a third embodiment of a patterned dam where the openings 34 are interconnected with one another and hexagonal. FIG. 5 shows a fourth embodiment of a patterned dam where the openings 35 are independent from one another and oblong. It should be noted that the patterns of the opening well structure in the embodiments and illustrations are described for exemplary purpose. The pattern of the opening well structure should be designed to correspond to how the chip die 2 is designed.

By using a photosensitive material coating or laminating on the substrate, an opening well structure with plurality of openings and pillars is formed by photolithography or mechanical processing to have patterns corresponding to the active sensor areas of the chip die so as to provide improved support on the substrate for the cover glass. The overall package structure is then reinforced without the risk of cracking the substrate.

Those skilled in the art will readily observe that numerous modifications and alterations of the device and method may be made while retaining the teachings of the invention. Accordingly, the above disclosure should be construed as limited only by the metes and bounds of the appended claims.

1: A chip scale package with patterned dam structure, comprising:
a substrate as a support structure for the chip scale package;
a chip die disposed on a top side of the substrate, the chip die having a plurality of sensor active areas with a plurality of lenses;
a dam layered on the top side of the substrate and covering the chip die, the dam having an opening well structure on the plurality of sensor active areas, the opening well structure comprising a plurality of pillars distributed on the chip die where a plurality of openings is formed among the plurality of pillars, the plurality of openings respectively corresponding in position to the plurality of sensor active areas, the plurality of pillars supported by the chip die; and
a cover glass layered on the dam and supported by the dam.

2: The chip scale package of claim 1, wherein the dam is made of photosensitive material and the opening well structure is formed by photolithography.

3: The chip scale package of claim 1, wherein the opening well structure of the dam is formed by laser engraving, dry etching, wet etching, mechanical drilling, or micromachining.

4: The chip scale package of claim 1, wherein the dam is coated or laminated on the substrate.

5: The chip scale package of claim 1, wherein the plurality of openings of the opening well structure is independent from one another and circle-shaped.

6: The chip scale package of claim 1, wherein the plurality of openings of the opening well structure is interconnected with one another and circle-shaped.

7: The chip scale package of claim 1, wherein the plurality of openings of the opening well structure is interconnected with one another and hexagonal.

8: The chip scale package of claim 1, wherein the plurality of openings of the opening well structure is independent from one another and oblong.

9: The chip scale package of claim 1, wherein the opening well structure with the plurality of openings and pillars is supportive to the substrate when a series of backside procedures is carried out on a bottom side of the substrate opposite to the top side.

10: The chip scale package of claim 1, wherein the chip die is an optoelectronic chip, a light sensor, a proximity sensor, a micro lens, or a CMOS image sensor.
